(19) United States
(12) Patent Application Publication
(10) Pub. No.: US 2015/0047435 A1
(43) Pub. Date: Feb. 19, 2015

(54) Micromechanical Measuring Element

(71) Applicant: EPCOS AG, München (DE)

(72) Inventors: Bernhard Ostrick, Teltow (DE); Michael Schiffer, Berlin (DE)

(21) Appl. No.: 14/383,862

(22) PCT Filed: Feb. 8, 2013
(86) PCT No.: PCT/EP2013/052548

§ 371 Date: Sep. 8, 2014

(30) Foreign Application Priority Data
Mar. 9, 2012 (DE) 10 2012 102 020.5

(51) Int. Cl. G01L 9/00; B81B 3/00

(52) U.S. Cl. CPC G01L 9/008; B81B 3/0021
USPC 73/716

(57) ABSTRACT

A micromechanical measuring element has a sensitive element that comprises a diaphragm with an underside and an upper side. The micromechanical measuring element also has a cap, which is connected directly to the sensitive element. The sensitive element and the cap form a first chamber, which has a first opening.

This patent application is a national phase filing under section 371 of PCT/EP2013/052548, filed Feb. 8, 2013, which claims the priority of German patent application 10 2012 102 020.5, filed Mar. 9, 2012, each of which is incorporated herein by reference in its entirety.

### TECHNICAL FIELD

A micromechanical measuring element is specified.

### BACKGROUND

Micromechanical measuring elements which are implemented as pressure sensors, for example, as differential, relative or as absolute pressure sensors, are known, at least within the company. Differential or relative pressure sensors normally require two pressure connections which, for example, carry moist, solvent-containing or corrosive media. Here, the media feed line to the pressure sensors must be separated from an electric contact-making means by a suitable construction and connecting technique, in order to protect the electric contact-making means from damage by the medium. Furthermore, the construction and connecting technique itself must be media-stable. As a result, the variety of possible bonding and jointing techniques is restricted.

Known differential or relative pressure sensors based on piezo-resistive or capacitive sensor elements operate with one or with multiple measuring elements. Here, in known differential pressure sensors which have a sensitive measuring element, the media feed lines are normally arranged on two opposite sides, which means that a pressure to be measured is fed in via the rear side, while the ambient or reference pressure acts on the front side of the measuring diaphragm. As a result, it is absolutely necessary to configure the housing of the pressure sensor in such a way that the media connections are either diverted to one side or are fitted to two different sides. Furthermore, conductor tracks and bonding wires, which are normally located on the upper side of the sensor element, are exposed to the reference medium. As a result, the areas of use of a non-protected sensor element are limited because of the inadequate chemical resistance. To increase the resistance, in order to protect the electric contact-making means and for the purpose of media separation, use is made either of a gel potting compound, wherein the transfer medium can be exposed freely to the environment, or use is made of metal diaphragms, wherein the transfer medium is separated from the surroundings and sensitive regions of the sensor element are protected by an internal medium, such as oil. The metal diaphragm can, for example, be part of a housing cover.

For the measurement of differential pressure or flow, systems based on at least two measuring elements are therefore often constructed. Known systems with two measuring elements need no media protection of the electric contacts but the elements must be matched to each other by a calibration process for accurate measurements.

The pressure sensors therefore normally either have at least two measuring elements which, although they are exposed to the measuring medium only on the rear side, require a complicated calibration process, or use is made of protective devices at the system level, which protect at least the active side of the sensitive element, such as contact pads and measuring bridges, from media attacks.

### SUMMARY OF THE INVENTION

Embodiments specify a micromechanical measuring element in which it is possible to dispense with complicated protective devices of the electric contacts.

A micromechanical measuring element according to at least one embodiment has a sensitive element. The sensitive element comprises a diaphragm, which has an underside and an upper side. For example, the sensitive element can be implemented in one piece. The sensitive element can in particular be implemented as a silicon chip which comprises a measuring diaphragm. The silicon chip can be produced, for example, from a silicon wafer, wherein the measuring diaphragm forms a thinned region, for example an etched-thin region of the silicon chip. The sensitive element is preferably implemented as a piezo-resistive element which has piezo-resistor structures, feed lines and contact-making surfaces on its upper side, which, here and in the following text, can also be referred to as an active side. Via a pressure-dependent deformation of the diaphragm and the piezo-resistor structures implanted therein, which, for example, are wired up to form a Wheatstone bridge, it is possible for a change in the electric output voltage of the Wheatstone bridge to occur as a result of the resistance change of the piezo-resistor structures, by which means the applied pressure or a pressure change can be determined. Alternatively, the sensitive element can also be implemented as a capacitive element, in which, for example, at least one capacitor is implemented in the silicon chip. When pressure is applied, the capacitance of the capacitor is changed, by which means a pressure measurement is made possible.

The micromechanical measuring element also has a cap, which is connected directly to the sensitive element. This can mean in particular that the cap is fixed directly to the sensitive element. The cap can, for example, be formed in one piece.

The sensitive element and the cap preferably form a first chamber. The first chamber has at least one first opening. For example, the sensitive element and the cap form a cavity, which is accessible from outside only by the first opening. The first chamber is preferably filled with a first medium, for example, with oil.

According to one development, the micromechanical measuring element has at least one contact-making surface. The at least one contact-making surface is preferably arranged on the sensitive element and is used to make electric contact with the sensitive element. For example, the at least one contact-making surface can be formed as a contact pad.

According to one development, the upper side of the diaphragm is accessible to the first medium by the first opening. The first medium can in particular be in direct contact with the upper side of the diaphragm and transfer an applied pressure to the diaphragm.

According to one development, the sensitive element is connected directly to a carrier on a side facing away from the cap. For example, the sensitive element is fixed directly to the carrier. The sensitive element and the carrier form a second chamber, which preferably has a second opening. The second chamber can in particular represent a cavity, which is accessible from outside by the second opening. The second chamber is preferably filled with a second medium. Here and in the following text, the first and the second medium can also be referred to as a measuring medium or a transfer medium.

According to one development, the underside of the diaphragm is accessible to the second medium by the second opening. In particular, the second medium can be in direct contact with the underside of the diaphragm and transfer a pressure to the diaphragm.

In the measuring elements described here, both the pressure supplies, which means the transfer of a pressure to be measured to the diaphragm, and the media separation, which means the separation of the first medium from the second medium, are implemented by the specific configuration of carrier and cap and the respective openings at the chip level. This implementation can also be referred to as zero level packaging or chip level packaging. Advantageously, as a result the sensitive element can be processed further simply without the contact-making surface or else bonding wires needing to be protected in a complicated way from media attacks. The cap and the carrier form protective and stabilizing elements, which guarantee media separation and permit a differential or relative pressure measurement.

According to one development, the second opening is formed in the carrier. For example, the carrier can have a hole which forms the second opening. The second opening can, for example, run through the carrier in a direction which is approximately parallel to a main propagation direction of the diaphragm of the sensitive element. Alternatively, the second opening can run in a direction which is approximately perpendicular to a main propagation direction of the diaphragm of the sensitive element.

According to one development, the second opening is formed in the sensitive element. The sensitive element can, for example, have a hole which forms the second opening. The second opening preferably runs through the sensitive element in a direction which is approximately parallel to a main propagation direction of the sensitive element.

According to one development, the second opening is formed in such a way that it offers the second medium an access to the upper side of the diaphragm. As a result, an applied pressure to be measured can be transferred to the diaphragm via the second medium.

According to one development, the first opening is formed in the cap. The cap can, for example, have a hole which forms the first opening. For example, the first opening can run in a direction which is approximately parallel to the second opening running through the carrier or the sensitive element.

According to one development, the first opening runs through the sensitive element and the carrier. For example, the first opening can be produced by a hole through the carrier and the sensitive element.

According to one development, the first opening is formed in such a way that it offers the first medium an access to the upper side of the diaphragm. As a result, an applied pressure to be measured can be transferred to the diaphragm via the first medium.

According to one development, the measuring element has a plurality of outer sides. For example, the measuring element can be formed in the shape of a cube, in the shape of a die or in the shape of a disk and/or have external dimensions which give the measuring element a form in the shape of a cube, in the shape of a die or in the shape of a disk. The outer sides can also form any other desired geometric form. The first opening and the second opening are preferably arranged on the same outer side of the measuring element.

By the measuring element described here, as a result of the arrangement of the media feed lines fitted to one side, i.e. the first and the second opening a simplification of a housing, which can be formed by the cap and the carrier, at the system level is achieved, since the media connections can be produced in one process step.

According to one development, the at least one contact-making surface is arranged on the sensitive element on a side of the sensitive element that faces the cap. The at least one contact-making surface is preferably arranged at least partly outside the cap. According to a preferred development, the at least one contact-making surface is arranged completely outside the cap. The electric contact-making means of the sensitive element or of the silicon chip is consequently separated from the media connections of the measuring element. As a result, it is advantageously possible to achieve the situation in which the at least one contact-making surface does not have to be protected from the measuring medium by complicated measures.

According to one development, the measuring element is formed as a relative pressure sensor. The relative pressure sensor determines, for example, the relative pressure measurement as a pressure difference measurement with respect to the atmospheric pressure.

According to one development, the measuring element is formed as a differential pressure sensor. Here, the differential pressure sensor measures a differential pressure, which is determined as the difference between two pressures.

According to one development, the measuring element is formed as a volume flow sensor and/or flow sensor. In particular, the measuring element can be implemented as a miniaturized volume flow sensor and/or as a miniaturized flow sensor. Here, a pressure difference is measured before and after a cross-sectional narrowing of a measuring channel which, for example, is formed by an aperture, said pressure difference behaving proportionally in relation to the volume flow and thus, by using a suitable calibration, permitting a flow measurement or volume flow measurement. With the aid of the Bernoulli equation, given the same hydrostatic pressure, the volume flow can be calculated by using the pressure difference before and after the cross-sectional narrowing.

According to one development, the sensitive element has resistance structures and feed lines. The resistance structures form, for example, a piezo-resistive measuring bridge for the pressure and/or flow measurement. The resistance structures and the feed lines are preferably implanted in the sensitive element, particularly preferably in the silicon chip.

According to one development, the measuring bridge is formed by additional functional layers. These functional layers can be applied to the sensitive element or to the diaphragm, for example, by vapor deposition or sputtering.

According to one development, the carrier comprises glass or consists of glass. Furthermore, it is possible for the carrier to comprise silicon or to consist of silicon.

According to one development, the cap comprises glass or consists of glass. It is also possible for the cap to comprise silicon or to consist of silicon.

According to one development, the parts of the measuring element that are exposed to the measuring medium, such as the cap and/or carrier or parts of the cap and/or the carrier, can have borosilicate glass, silicon and/or LPCVD silicon nitride or consist of one of these materials. As a result, the measuring element is also suitable for moist and/or corrosive media.

### BRIEF DESCRIPTION OF THE DRAWINGS

Exemplary embodiments of micromechanical measuring elements are explained below with reference to FIGS. 1 to 3.

In the exemplary embodiments and figures, the same or constituent parts with the same effect can each be provided with the same designations. The elements illustrated and the size relationships thereof to one another are in principle not to be viewed as to scale. Instead, individual elements, such as layers, components and regions, can be illustrated exaggeratedly thickly or largely dimensioned for the purpose of better illustration and/or for better understanding.

In the drawings:

FIG. 1 shows a schematic sectional view of a micromechanical measuring element according to a first exemplary embodiment, wherein the first opening runs through the sensitive element and the carrier;

FIG. 2 shows a schematic sectional view of a micromechanical measuring element according to a further exemplary embodiment, wherein the first opening is formed in the cap and the second opening in the carrier; and

FIG. 3 shows a schematic sectional view of a micromechanical measuring element according to a further exemplary embodiment, wherein the second opening is formed in the sensitive element.

### DETAILED DESCRIPTION OF ILLUSTRATIVE EMBODIMENTS

FIG. 1 shows a micromechanical measuring element 1 in a schematic sectional illustration. The micromechanical measuring element 1 is implemented as a piezo-resistive measuring element and has a sensitive element 2 which comprises a diaphragm 21. The sensitive element 2 is a silicon chip, which is produced from a silicon wafer. The diaphragm 21 has an underside 211 and an upper side 212.

The micromechanical measuring element 1 also has a carrier 6 and a cap 3. In the exemplary implement shown, the carrier 6 and the cap 3 have glass and, with the sensitive element 2, form a silicon-glass composite. The cap 3 is connected directly to the sensitive element 2, by which means the cap 3 is attached at the chip level. The sensitive element 2 and the cap 3 form a first chamber 4, the first chamber 4 having a first opening 5. The first opening 5 is formed by a cutout in the sensitive element 2 and by a cutout in the carrier 6. The upper side 212 of the diaphragm 21 is accessible to a first medium by the first opening 5. The first medium can thus transfer an applied pressure to the diaphragm 21.

The sensitive element 2 is connected directly to a carrier 6 on the side facing away from the cap. Here, the sensitive element 2 and the carrier 6 form a second chamber 7. The second chamber 7 has a second opening 8. The first and the second opening 5, 8 are produced, for example, by a laser drilling. The underside 211 of the diaphragm 21 is accessible to a second medium by the second opening 8, by which means the second medium can transfer an applied pressure to the diaphragm 21. Feed lines to the diaphragm 21 are formed on both sides by the first and the second opening 5, 8.

A one-sided arrangement of the media connections, which means a one-sided arrangement of the first and the second opening 5, 8, is implemented in the exemplary embodiment shown by two through holes in the silicon-glass composite. As compared with known measuring elements, during the production of a measuring element 1 shown in FIG. 1, only one additional etching step is necessary, the diaphragm of a respectively adjacent measuring element being etched through by an additional etching step. This can be implemented in a so-called batch process.

The micromechanical measuring element 1 also has a contact-making surface 9, which is implemented as a so-called contact pad and which is used to make electric contact with the measuring element 1. The contact-making surface 9 is arranged on the sensitive element 2 and is located outside the first chamber 4 and outside the second chamber 7. The electric contact-making means of the sensitive element 2 is separated from the media connections. As a result, it is possible to ensure that the contact-making surface 9 does not come into contact with a medium located in the first or second chamber 4, 7, by which means the contact-making surface 9 is effectively protected from media attacks, for example, by corrosive media. Corrosion of electric feed lines, such as the contact-making surface or bonding wires, can already be prevented at the chip level in the measuring element shown. During the production of a measuring element according to the exemplary embodiment shown in FIG. 1, the electric contact-making direction is the same as the mounting direction of the sensitive element 2.

Alternatively, it is possible for the measuring element 1 to have multiple contact-making surfaces for making contact with the measuring element 1 and/or the sensitive element 2.

Furthermore, the micromechanical measuring element 1 has resistance structures 22 and feed lines 23, which are implanted in the sensitive element 2. The resistance structures 22 and feed lines 23 form a measuring bridge for the pressure measurement.

The micromechanical measuring element 1 in the exemplary embodiment shown is implemented as a relative or differential pressure sensor, wherein a media transfer line is implemented at the chip level and the media are fed in from an underside of the measuring element, that is to say a side of the measuring element that faces away from the cap.

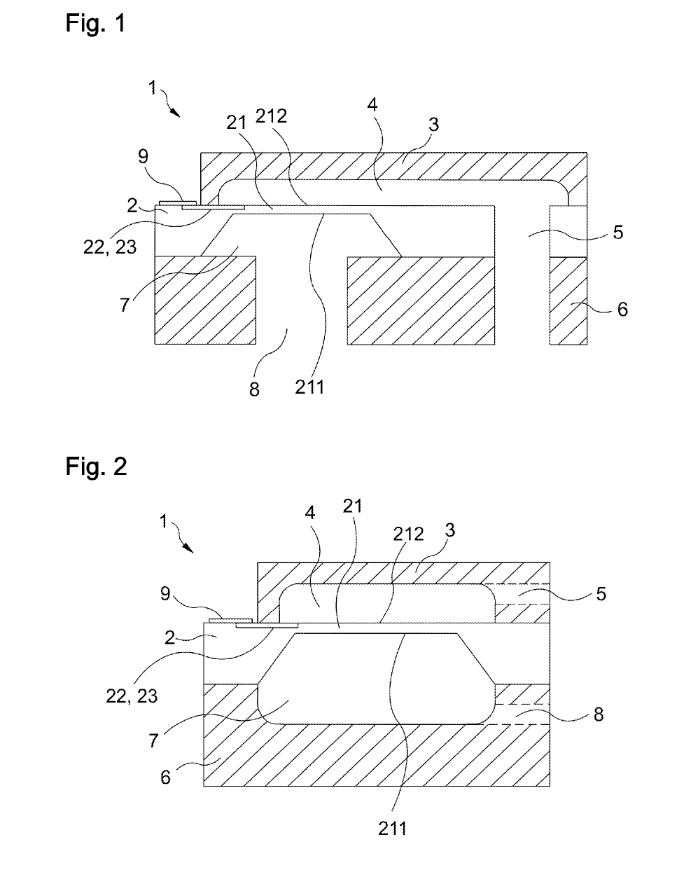

A micromechanical measuring element 1 is shown in FIG. 2 in a schematic sectional illustration according to a further exemplary embodiment. As distinct from the exemplary embodiment from FIG. 1, the first opening 5 is formed in the cap 3. In order to produce the first opening 5 and the second opening 8, a hole is respectively drilled into the cap 3 and into the carrier 6, preferably by a laser.

Also in the exemplary embodiment shown in FIG. 2, the contact-making surface 9 is protected from detrimental influences of a contact with a measuring medium, as a result of the arrangement of said contact-making surface outside the chambers 4, 7 filled with media. As distinct from the exemplary embodiment shown in FIG. 1, the electric contact-making direction is perpendicular to a mounting direction of the sensitive element 2.

The micromechanical measuring element 1 in the exemplary embodiment shown is implemented as a relative or differential pressure sensor, wherein a media transfer line is implemented at chip level and the media are fed in from a side of the measuring element which connects an underside and an upper side of the measuring element, wherein the underside is determined by a side of the measuring element that faces away from the cap, and the upper side is determined by a side of the measuring element that faces the cap.

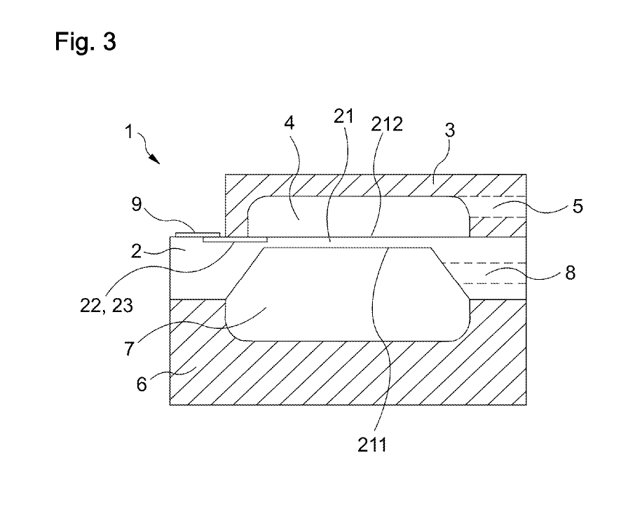

FIG. 3 shows a micromechanical measuring element 1 in a schematic sectional illustration according to a further exemplary embodiment. As distinct from the exemplary embodiment from FIG. 2, the second opening 8 is formed in the sensitive element.

The first opening 5 and the second opening 8 in the exemplary embodiment shown are implemented in the cap 3 and in the sensitive element 2, preferably by laser drillings.

The micromechanical measuring element 1 in the exemplary embodiment shown is likewise implemented as a relative or differential pressure sensor, wherein a media transfer line is implemented at the chip level and the media are once more fed in from a side of the measuring element which connects the underside and upper side of the measuring element.

The invention is not restricted to the exemplary embodiments through the description by using the latter but comprises any new feature and any combination of features. This includes, in particular, any combination of features in the patent claims, even if this feature or this combination is itself not explicitly specified in the patent claims or exemplary embodiments.

1-15. (canceled)

16. A micromechanical measuring element, comprising:
a sensitive element that includes a diaphragm with an underside and an upper side;
a cap connected directly to the sensitive element, wherein the sensitive element and the cap form a first chamber and wherein the first chamber has a first opening; and
a contact-making surface making electric contact with the sensitive element.

17. The measuring element according to claim 16,
wherein the sensitive element is connected directly to a carrier on a side facing away from the cap;
wherein a second chamber is formed by the sensitive element and the carrier; and
wherein the second chamber has a second opening.

18. The measuring element according to claim 17,
wherein the upper side of the diaphragm is accessible to a first medium by way of the first opening; and
wherein the underside of the diaphragm is accessible to a second medium by way of the second opening.

19. The measuring element according to claim 17, wherein the second opening is formed in the carrier.

20. The measuring element according to claim 17, wherein the second opening is formed in the sensitive element.

21. The measuring element according to claim 17, wherein the first opening runs through the sensitive element and the carrier.

22. The measuring element according to claim 17,
wherein the measuring element has a plurality of outer sides; and
wherein the first opening and the second opening are arranged on the same outer side.

23. The measuring element according to claim 17, wherein the carrier comprises glass.

24. The measuring element according to claim 17, wherein the carrier comprises silicon.

25. The measuring element according to claim 16, wherein the first opening is formed in the cap.

26. The measuring element according to claim 16,
wherein the contact-making surface is arranged on the sensitive element on a side of the sensitive element that faces the cap; and
wherein the contact-making surface is arranged at least partly outside the cap.

27. The measuring element according to claim 16, wherein the measuring element comprises a relative and/or differential pressure sensor.

28. The measuring element according claim 16, wherein the measuring element comprises a volume flow sensor and/or flow sensor.

29. The measuring element according to claim 16, wherein the sensitive element has resistance structures and feed lines, which form a piezo-resistive measuring bridge for a pressure measurement and/or a flow measurement.

30. The measuring element according to claim 29, wherein the measuring bridge is formed by functional layers.

31. The measuring element according to claim 16, wherein the cap comprises glass.

32. The measuring element according to claim 16, wherein the cap comprises silicon.
